(19) United States
(12) Patent Application Publication
(10) Pub. No.: US 2010/0182743 A1
(43) Pub. Date: Jul. 22, 2010

(54) UNIVERSALTHERMOSTAT EXPANSION PORT

(75) Inventor: Michael A. Roher, Fort Wayne, IN (US)

Correspondence Address: MARJAMA MULDOON BLASIAK & SULLIVAN LLP, 250 SOUTH CLINTON STREET, SUITE 300, SYRACUSE, NY, 13202, US

(73) Assignee: CARRIER CORPORATION, Farmington, CT (US)

(21) Appl. No.: 12/521,313

(22) PCT Filed: Dec. 29, 2006
(86) PCT No.: PCT/US06/49616

§ 371 Date: Mar. 1, 2010

(51) Int. Cl. G06F 12/02; G06F 1/16; G06F 13/00; H05K 13/00

(52) U.S. Cl. 361/679.41; 711/170; 710/301; 29/825; 711/E12.002

(57) ABSTRACT

In one aspect, the invention relates to a configurable thermostat including a thermostat core having a user interface. The user interface includes a plurality of user interface keys, a display, a temperature sensor, and a temperature control. The configurable thermostat also includes a universal thermostat expansion port. The universal thermostat expansion port is disposed on the thermostat core. The universal thermostat expansion port includes at least one electrical connector. The electrical connector electrically couples a daughter board to the thermostat core, wherein the daughter board is communicately coupled to the thermostat core by an ASCII communications protocol. According to another aspect of the invention, a method for configuring a thermostat uses a personal computer with a thermostat having a user removable memory. Yet another aspect of the invention is a method for rapidly producing a thermostat having new features without needing to redesign the entire thermostat.

### FIELD OF THE INVENTION

This invention relates generally to a thermostat that can be adapted to provide new features and more specifically to a thermostat that can be adapted to provide new communication and memory features.

### BACKGROUND OF THE INVENTION

Early thermostats began as simple temperature switches typically having only two states, “room temperature satisfied” or “call for heat”. By contrast, most thermostats today are relatively complicated devices incorporating a microcomputer running on firmware. New thermostat product design cycles can be time consuming and typically involve many technical specialties. With each new thermostat design cycle, there can be mechanical design needed for a new housing, electronics design for a new circuit and circuit board design, and computer hardware and software design for a new embedded microcomputer application having new microcomputer software. The once mostly electro-mechanical thermostat design process has evolved into a complex development cycle. The development cycle for a modern thermostat can range from several months to over one year from concept to production.

With microcomputer based thermostats, it is also possible for both residential and commercial thermostats to communicate via a communications network. Current network communicating thermostat designs typically use a proprietary network connection to transport data between the thermostat and another computer or controller on the network. For example, some thermostats manufactured by the Carrier Corporation make use of the Carrier communications network (“CCN”) protocol. Other designs, such as legacy home X-10 based thermostats, have used the X-10 power line communication protocol as part of the thermostat design. Such X-10 based thermostats, however, can only be sold as relatively special purpose thermostats dedicated to a very limited market.

What is needed is a thermostat that can adapt to various connectivity methods and memory configurations without requiring the initiation of new thermostat design cycle for yet another special purpose thermostat product.

### SUMMARY OF THE INVENTION

In one aspect, the invention relates to a configurable thermostat including a thermostat core having a user interface. The user interface includes a plurality of user interface keys, a display, a temperature sensor, and a temperature control. The configurable thermostat also includes a universal thermostat expansion port. The universal thermostat expansion port is disposed on the thermostat core. The universal thermostat expansion port includes at least one electrical connector. The electrical connector electrically couples a daughter board to the thermostat core, wherein the daughter board is communicately coupled to the thermostat core by an ASCII communications protocol.

According to another aspect of the invention, a method for configuring a thermostat using a personal computer comprising the steps of: providing a thermostat having a user removable memory; providing a personal computer; removing the user removable memory from the thermostat; connecting the user removable memory to the personal computer; communicating with the user removable memory using the personal computer; removing the user removable memory from the personal computer; reinstalling the user removable memory into the thermostat; and operating the thermostat in conjunction with the user removable memory to perform thermostat operational functions.

According to yet another aspect of the invention, a method for rapidly producing a thermostat having new features without needing to redesign the entire thermostat comprising the steps of: providing a thermostat core comprising a plurality of user interface keys, a display, an HVAC interface circuit, and a thermostat universal port; providing a requirement for a new thermostat feature that is not available in the thermostat core; designing a daughter board suitable for plugging into the universal thermostat expansion port having the new thermostat feature; producing the daughter board suitable for plugging into the universal thermostat expansion port; and plugging the daughter board into the universal thermostat expansion port to create a thermostat comprising the thermostat core and the daughter board and causing the thermostat to have the new thermostat feature.

### BRIEF DESCRIPTION OF THE DRAWINGS

For a further understanding of these and objects of the invention, reference will be made to the following detailed description of the invention which is to be read in connection with the accompanying drawing, where:

FIG. 1 shows a simplified block diagram of a thermostat according to the invention;

FIG. 2 shows a circuit board side view of one exemplary embodiment of a thermostat core 103;

FIG. 3A shows a wireless connectivity daughter board using the Zwave™ wireless chip;

FIG. 3B shows an exemplary daughter board including a symbolically represented Bluetooth wireless chip set;

FIG. 3C shows an exemplary daughter board having a symbolically represented wireless receiver configured to receive information from a broadcast signal;

FIG. 3D shows a daughter board including Infra-red (“IR”) communication;

FIG. 3E shows a daughter board having an SDIO socket for accepting a secure digital memory; and

FIG. 4 shows a symbolic representation of a system using a SD memory card to program a thermostat using a personal computer.

The drawings are not necessarily to scale, emphasis instead generally being placed upon illustrating the principles of the invention. In the drawings, like numerals are used to indicate like parts throughout the various views.

### DETAILED DESCRIPTION OF THE INVENTION

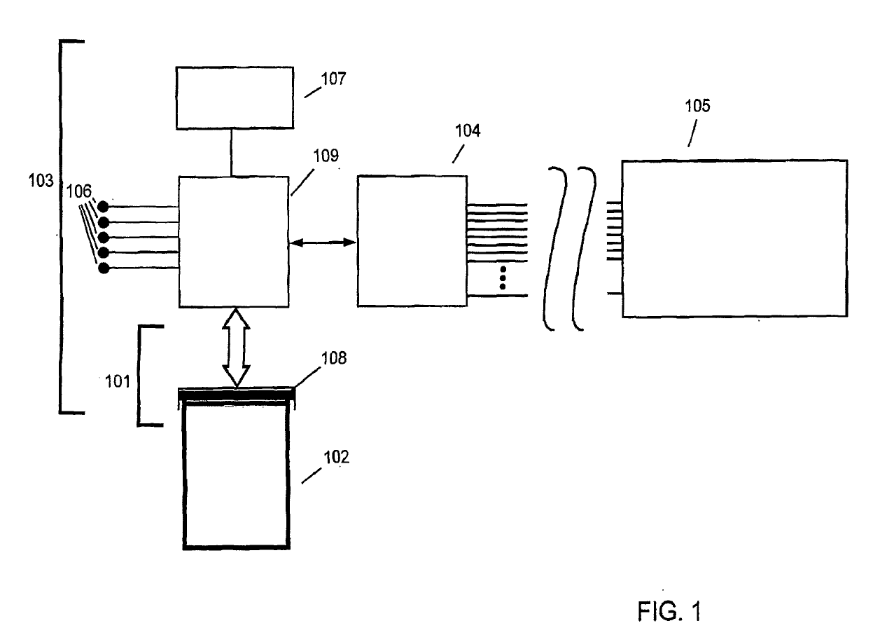

Prior to the inventive thermostat design described herein, new thermostat features and applications, such as related to additional memory or communication features, required an entirely new thermostat design cycle. As shown in FIG. 1, a solution to the problem of endless thermostat design cycles is to configure basic aspects of a thermostat 100, including user interface keys 106, display 107, microcomputer 109, HVAC interface 104, and universal thermostat expansion port 101 as a “thermostat core” 103. Using the inventive method, a thermostat core 103 design can then be configured with features usefully to a specific application by providing a suitable daughter board 102. Thus a design thermostat design cycle can be accomplished more quickly, efficiently, and inexpensively, since daughter board 102 can be the only subject of a new design cycle.

FIG. 1 shows a simplified block diagram of a thermostat according to the invention. Thermostat 100 includes a microcomputer 109, user keys 106, display 107, HVAC interface 104, and universal thermostat expansion port 101. User keys 106 and display 107 allow a user to interact with the thermostat in a conventional manner. HVAC interface 104 provides electrical controls suitable for controlling a HVAC comfort system 105 (not part of thermostat 100). A universal thermostat expansion port 101 electrical connector 108 can provide an electrical connection to and optional mechanical support for a daughter board 102. Electrical connector 108 can also optionally provide mechanical support for a daughter board 102. Universal thermostat expansion port 101 can take on a variety of physical form factors. In various embodiments of a thermostat core 103, there can be one or more electrical connectors to electrically couple a daughter board 102 to the thermostat core 103 creating a complete thermostat 100 having the additional features added by the daughter board 102. Communications between thermostat 100 and a daughter board 102 via universal thermostat expansion port 101 can be accomplished using ASCII character based commands.

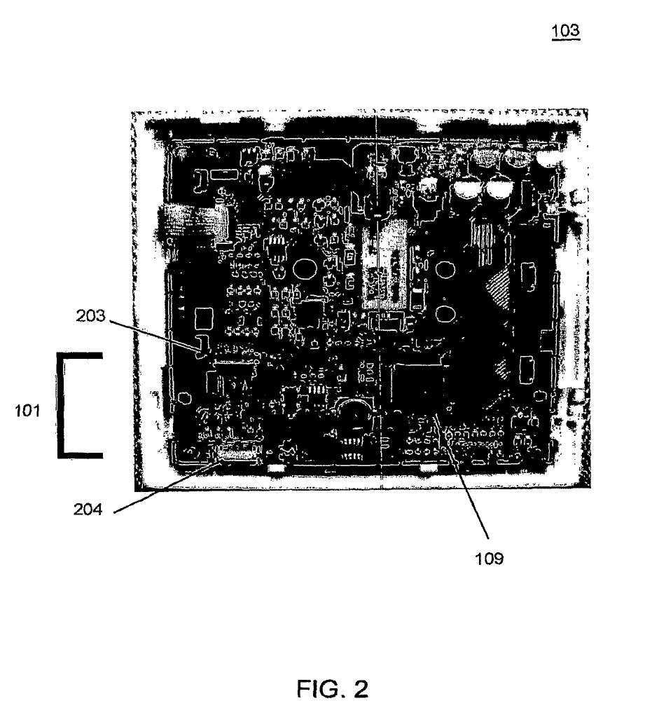

FIG. 2 shows a circuit board side view of one exemplary embodiment of a thermostat core 103 configured with a universal thermostat expansion port 101. In the embodiment of FIG. 2, two electrical connectors 203 and 204 provide both electrical connections and mechanical support for daughter board 102, not shown in FIG. 2. Exemplary connectors of the type shown in FIG. 2 are available from Hirose Electric (U.S.A.), Inc. of Simi Valley, Calif. It is noted that any suitable type of electrical connectors, 203 and 204 can be used. Also, as previously described, in other embodiments where mechanical support is provided by other suitable mounting structures, such as mechanical standoffs, one electrical connector 108 can suffice to provide power and communication connections between a thermostat core 103 and a daughter board 102.

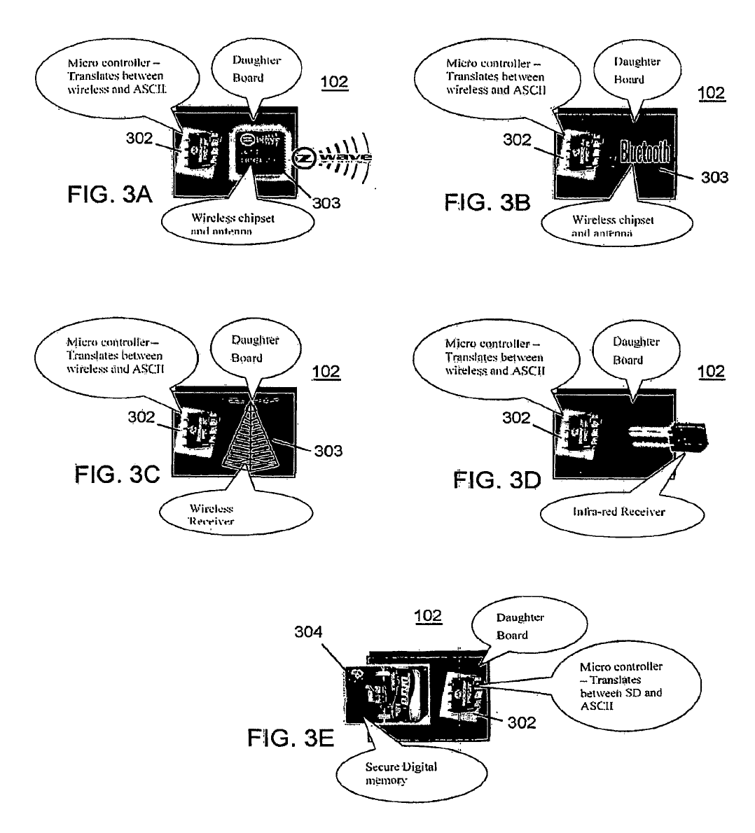

FIGS. 3A to 3E show a symbolic representation of various exemplary embodiments of daughter boards 102 according to the invention. FIG. 3A shows a wireless connectivity board using the Zwave™ wireless chip set 303 manufactured by Zensys Inc. of Fremont, Calif. Other suitable wireless networking chipsets are ZigBee™ and MiWi™ such as those offered by Microchip Technology Inc. of Chandler, Ariz. or any WiFi chipset compatible with the IEEE 802.11b/g wireless networking standard. Microcomputer 302, shown here as PIC™ type microcomputer also manufactured by Microchip Technology Inc. can perform, at least in part, the function of communicating ASCII commands to the universal thermostat expansion port on thermostat 100. Microcomputer 302 can also provide control and supervisory functions for the wireless chip set 303. Any suitable microcomputer can be used in place of the 8 pin PIC microcontroller shown in the figures. FIG. 3B shows an exemplary daughter board 102 including a symbolically represented Bluetooth wireless chip set. FIG. 3C shows an exemplary daughter board 102 having a symbolically represented wireless receiver configured to receive information from a broadcast signal, for example, a municipal notification and warning system, such as a digital channel of a municipal, state, or national emergency broadcasting system or other such radio data service. The embodiment shown in FIG. 3C can also be configured for use as part of a wide area wireless network, or with a cell or pager based radio communication system such as Verizon™ cell service, or the SkyTel™ 2-way paging system. FIG. 3D shows a daughter board 102 for adding Infra-red (“IR”) communication capability to a thermostat 100 symbolically represented by an IR receiver. Any suitable type of IR detector or IR receiver can be used in the embodiment of FIG. 3D. FIG. 3E shows a daughter board 102 having an SDIO socket for accepting a secure digital memory card to a thermostat 100.

While the various exemplary embodiments shown in FIG. 3A-FIG. 3E mostly apply to memory or communication features added to a thermostat 100 via a daughter board 102, it is should also be noted that a universal thermostat expansion port as described herein is not limited to memory and communication applications. One aspect of the universal thermostat expansion port is that a thermostat 100 can be tailored to a new application by simply designing a new daughter board 102 having the needed new features or functionality to satisfy the new application. It should also be noted that where a daughter board includes an additional socket, such as, but no limited to, an SDIO socket, additional flexibility is achieved where a variety of custom or “off the shelf” solutions can be supplied in that standard form factor. For example, while the example of FIG. 3E illustrated an SDIO socket for accepting SD memory, several types of wireless communication cards are presently available that can plug directly into an SDIO socket. Thus a thermostat 100 base product can have a far longer usable life time because of the flexibility offered by feature expansion or upgrade through the use of new daughter board products 102. Such flexibility can be achieved by the inventive combination of a universal thermostat expansion port with a defined ASCII communications protocol.

Having described various exemplary embodiments of the electrical connections between thermostat 100 and daughter boards 102, we now turn to an exemplary ASCII communications protocol useful for communicating between thermostat core 103 and daughter board 102. An ASCII communications protocol provides a list of defined ASCII commands for communicating with thermostat 100. The ASCII command set can be common for all new thermostat designs incorporating a universal thermostat expansion port. By incorporating a common universal thermostat expansion port ASCII command set within many of the thermostats designed and produced by a particular company, additional memory and communications functionality can be relatively easily added at a later date. One aspect of the flexibility created by a universal thermostat expansion port 101 is that as new memory and communications types are developed, only new daughter boards 102 need to be developed for existing thermostat core 103 designs. Any supervisory functions needed for a particular communications chip set or memory located on a daughter board 102 can be performed by microcomputer 302. Microcomputer 302 can also provide translation functions between external commands and the standard ASCII command set, although standard commands can also be transmitted directly from an external device or system to a daughter board 102. The follow examples show exemplary ASCII communication commands useful for communication between a thermostat 100 and a daughter board 102.

In the examples that follow, ASCII commands use a standard ASCII character set as defined by the ASCII (American Standard Code for Information Interchange) Code. “NAK” is the standard ASCII character for “negative acknowledge” or “negative acknowledgement”.

### Example 1

The exemplary command: T1HTSP!68, 01:30, results in a response: T1HTSP: ACK. The command “T1HTSP!68, 01:30” sets a heat setpoint for System 1, Zone 5 to 68 at current system units. An override timer is initiated at 1 hour 30 minutes. A corresponding ASCII command definition reads as: Set the current Heat Setpoint send: T1HTSP!XX,HH:MM (Time is optional); response: T1HTSP: ACK/NAK sets the current heat setpoint for the specified thermostat. An override timer will be initiated at the default of 2 hours 00 minutes. Follow with override time if a different value is desired. A “NAK” will be returned if the heat setpoint is not valid for the current unit type. It can be the responsibility of external ASCII application software to ensure that correct setpoint values are sent for the current units (English/metric) setting. In one embodiment, setpoint, hours and minutes are sent with a leading zero for values less than 10.

### Example 2

The exemplary command: T1CFGEM!M T1CFGEM:ACK; Sets the units of the thermostat to Metric units (e.g. degrees Celsius vs. degrees Fahrenheit). A corresponding ASCII command definition reads as: Set Units of the thermostat. Send: T1CFGEM!E/M; response: T1CFGEM:ACK/NAK. Sets the units of the thermostat to English (E) or Metric (M).

### Example 3

The exemplary command: sent T1PGMMONWAKE!06:30 A, 70, 72, AUTO, receives a response of T1PGMMONWAKE:ACK. The example 3 command sets the time for the Monday Wake Period to 6:30 AM. The heat setpoint is set to 70 and the cool setpoint to 72, at current system units. Also, the fan is set to “auto”. A corresponding ASCII command definition reads as: Retrieve programming information for the Monday Wake Period by sending: T1PGMMONWAKE?; response: T1PGMMONWAKE: TIME (HH:MM A/P), HEAT, COOL, FAN returns time (12 hour format), heat setpoint, cool setpoint and fan settings for the “Monday Wake Period”. In this exemplary embodiment, if a programmable FAN is set to “OFF” the fan setting will not be returned, and if Periods Per Day is set to 2 a “NAK” will be returned.

The previous three example sets of ASCII communication between a thermostat core 103 and a daughter board 102 are merely illustrate of how to provide an ASCII communication protocol according to the invention. It is unimportant whether the particular exemplary commands used in examples 1 to 3 are present in order to implement a universal thermostat port 101 according to the invention. Any suitable ASCII command set that can establish sufficient control and information exchange with a base thermostat core 103 can be used. Preferably such a command set allows use of all available features of the thermostat core 103, however a substantial subset of available features can also be used in support of control and information exchange with a thermostat core 103.

Returning now to the various embodiments of exemplary daughter boards described with respect to FIG. 3A to FIG. 3E, the following examples illustrate applications for thermostats 100 configurable to a specific application.

### Example 4

A regional government provides a service to notify operators of comfort systems of an impending energy shortage. Signals are sent out by the regional government in a broadcast mode using a broadcast radio data service, in the form of a digital transmission. Such transmissions are similar to the digital transmissions used by many FM radio stations to display the name of a song currently playing on a radio display. Signals are sent in a standard format as chosen and specified by the regional government. Using the notice of impending energy shortage, thermostats equipped to receive the notification via the radio data service can take an appropriate action. One embodiment of a thermostat 100 having a thermostat core 103, universal thermostat port 101, and communications daughter board 102 can be so configured. Such actions can include setting the setpoint temperature lower in the winter or higher in the summer. A manufacturer of a thermostat core according to the invention needs only design and produce a suitable daughter board 102 having a radio receiver to receive the radio data service transmission and a microcomputer to translate the received notifications from the regional government into a standard set of ASCII commands corresponding to the desired actions to be taken for each specifically defined notification. For example, were there to a be a legislative mandate that all thermostats go to 68 degrees F. at midnight and 82 degrees F. at noontime, during an energy shortage, signals of an energy shortage received in a radio service transmission can be interpreted by the microcomputer on the daughter board and translated into standard ASCII commands to accomplish the above mentioned conservation settings of 68 degrees F. at midnight and 82 degrees F. at noontime. A later received notification that the energy shortage is over could be interpreted and translated to restore a thermostat 100 programmed temperature time setpoint profile.

### Example 5

A manufacturer of thermostats plans a thermostat product using user accessible memory cards such as “SD” flash memory cards. Rather than design an entirely new thermostat, a daughter board 102 having a standard SDIO socket for accepting flash memory cards can be designed. Such a board may or may not be supplemented by an additional microcomputer to provide additional functionality, including optional user applications such as data logging thermostat activity including time temperature profiles as recorded by the thermostat, or energy usages profiles related to thermostat on/off time for heating and/or cooling. The user of such a SD memory card capable thermostat can unplug the memory to read data logs and to display them on the screen of a personal computer configured to accept and read SD cards. It is understood that a personal computer is any type of standalone or networked computer including so called IBM compatible computers capable of running MS Windows™ or other operating system such as LINUX, APPLE™ computers, desktop, notebook, tablet, and handheld computers that have the capability to communicatively couple to a thermostat user removable memory, such as an SD card.

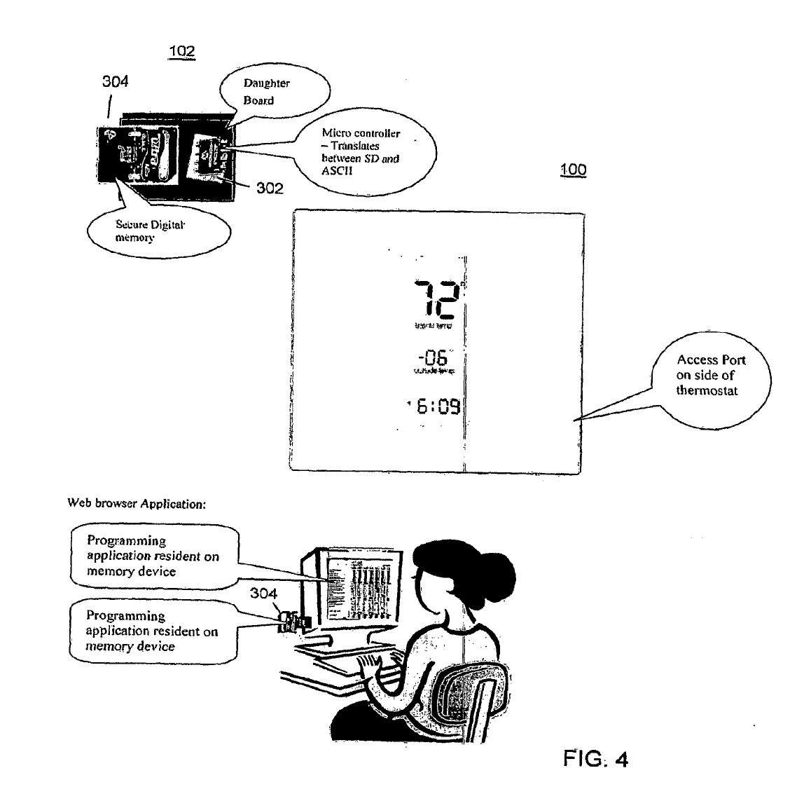

As illustrated in FIG. 4, a user can program a thermostat by programming a SD memory card, including time temperature profiles, using a program running on the SD card using a personal computer having an easy to use graphical user interface. The user can then plug the SD card into the thermostat to achieve customized programming without having to run through various menus and setup temperature setpoints using only the keys of a thermostat user interface. For example a classic “5 day 2 day” time setpoint chart having 4 setpoints per day could easily be displayed and setup on user grid allowing the thermostat user to see all settings laid out on a single grid or spreadsheet type of display. Similarly, it can be convenient to so program a programmable thermostat using such a chart where each week and weekend day can be programmed differently, instead of the “5 day 2 day” programming which was intended to simplify programming by thermostat user interface buttons alone using only two different profiles, one for weekdays (the “5”) and another profile for weekends (the “2”). It should be noted that the application program for programming the thermostat can also reside on the personal computer.

### Example 6

A thermostat core using a daughter board having an SDIO socket can accept a wireless card configured to plug into any socket complying with the SDIO socket standard. In this example, such a daughter board although restricted to SDIO compatible cards, can optionally accept either an SD memory card or a wireless card in an SDIO compatible form factor.

### Example 7

A thermostat core accepts a daughter board having both additional memory and wireless capability. Such dual function daughter boards can be accomplished either with the advent of SDIO dual function boards, yet to be marketed, or can be accomplished merely be assembly the necessary additional memory and radio chip sets directly onto a daughter board 102, the daughter board 102 having at least one electrical connector as previously described, to plug into a thermostat core 103.

In general applications involving control of a thermostat by an external authority such as a government agency, such as was illustrated in example 4, a thermostat 100 having a universal thermostat expansion port 101 is particularly well suited to accept a daughter board 102 to tailor a thermostat core to the application. Such control can also be accomplished by private entities, such as home and commercial comfort systems that can be remotely controlled individually or in groups by a commercial entity, rather than by a government, for purposes such as energy conservation.

While the present invention has been particularly shown and described with reference to the preferred mode as illustrated in the drawing, it will be understood by one skilled in the art that various changes in detail may be effected therein without departing from the spirit and scope of the invention as defined by the claims.

We claim:

1. A configurable thermostat comprising:
a thermostat core including a user interface, said user interface having a plurality of user interface keys, a display, a temperature sensor, and a temperature control; and
a universal thermostat expansion port, said universal thermostat expansion port disposed on said thermostat core, said universal thermostat expansion port including at least one electrical connector, said electrical connector to electrically couple a daughter board to said thermostat core, wherein said daughter board is communicately coupled to said thermostat core by an ASCII communications protocol.

2. The configurable thermostat of claim 1, wherein said daughter board includes memory.

3. The configurable thermostat of claim 2, wherein said memory is SD memory.

4. The configurable thermostat of claim 3, wherein said SD memory is disposed in an SDIO socket situated on said daughter board.

5. The configurable thermostat of claim 1, wherein said daughter board includes a wireless communications chip set.

6. The configurable thermostat of claim 5, wherein said daughter board includes a wireless communications chip set configured for WiFi wireless network connectivity.

7. The configurable thermostat of claim 1, wherein said daughter board includes a wireless receiver configured to receive information from a broadcast signal.

8. The configurable thermostat of claim 5, wherein said daughter board includes a microcomputer, said microcomputer including programming to translate an electrical and a communication protocol between said communications chip set and said thermostat core.

9. The configurable thermostat of claim 1, wherein said at least one electrical connector mechanically supports said daughter board.

10. A method for configuring a thermostat using a personal computer comprising the steps of:
providing a thermostat having a user removable memory;
providing a personal computer;
removing said user removable memory from said thermostat;
connecting said user removable memory to said personal computer;
communicating with said user removable memory using said personal computer;
removing said user removable memory from said personal computer;
reinstalling said user removable memory into said thermostat; and
operating said thermostat in conjunction with said user removable memory to perform thermostat operational functions.

11. The method of claim 10, wherein the step of providing a thermostat having a user removable memory comprises the step of providing a thermostat having an SD user removable memory.

12. The method of claim 10, wherein the step of providing a thermostat having a user removable memory comprises the step of providing a thermostat having an SD user removable memory in an SDIO form factor.

13. The method of claim 10, wherein the step of providing a thermostat having a user removable memory comprises the step of providing a thermostat having a user removable memory including a user application program for programming said thermostat.

14. The method of claim 10, wherein the step of providing a thermostat having a user removable memory comprises the step of providing a thermostat having a user removable memory, said user removable memory including a user application program for data logging thermostat activity.

15. A method for rapidly producing a thermostat having new features without needing to redesign the entire thermostat comprising the steps of:
providing a thermostat core comprising a plurality of user interface keys, a display, an HVAC interface circuit, and a universal thermostat expansion port;
providing a requirement for a new thermostat feature that is not available in said thermostat core;
designing a daughter board suitable for plugging into said universal thermostat expansion port having said new thermostat feature;
producing said daughter board suitable for plugging into said universal thermostat expansion port; and
plugging said daughter board into said universal thermostat expansion port to create a thermostat comprising said thermostat core and said daughter board and causing said thermostat to have said new thermostat feature.

16. The method of claim 15, wherein said new thermostat feature is a wireless communication feature.

17. The method of claim 15, wherein said new thermostat feature is a memory card feature.
